(19) United States
(12) Patent Application Publication
(10) Pub. No.: US 2026/0296129 A1
(43) Pub. Date: Oct. 1, 2026

(54) THERMAL COOLING SYSTEM

(71) Applicant: Rivian IP Holdings, LLC, Irvine, CA (US)

(72) Inventors: Mohammad Reza DANESH KADIVAR, Santa Clara, CA (US); Justin Xavier HOWER, Santa Clara, CA (US); Michael Alan KOKEN, Sunnyvale, CA (US); Rubab KADAM, Sunnyvale, CA (US)

(21) Appl. No.: 19/096,407

(22) Filed: Mar. 31, 2025

(51) Int. Cl. B60H 1/00; H05K 7/20

(52) U.S. Cl. CPC B60H 1/00278; H05K 7/20254

(57) ABSTRACT

A thermal cooling system includes a cold plate defining a channel and a pipe extending through the channel. The thermal cooling system includes a layer of compressible thermal interface material (TIM) extending around a perimeter of the pipe. The thermal cooling system includes a heat spreader configured to absorb heat generated by one or more heat sources, the heat spreader further configured to transfer at least a portion of the absorbed heat to the pipe via the layer of compressible TIM.

### INTRODUCTION

The present disclosure relates to thermal cooling and, more particularly, to a thermal cooling system for dissipating heat from one or more printed circuit board assemblies.

### SUMMARY

In one embodiment, a thermal cooling system is provided. The thermal cooling system includes: a cold plate defining a channel; a pipe extending through the channel; a layer of compressible thermal interface material (TIM) extending around a perimeter of the pipe; and a heat spreader configured to absorb heat generated by one or more heat sources, the heat spreader further configured to transfer at least a portion of the absorbed heat to the pipe via the layer of compressible TIM.

In another embodiment, a thermal cooling system for printed circuit board assemblies is provided. The thermal cooling system includes: a cold plate defining a channel; a pipe extending through the channel; a layer of compressible thermal interface material (TIM) extending around a perimeter of the pipe; and a heat spreader configured to absorb heat generated by one or more printed circuit board assemblies (PCBAs), the heat spreader further configured to transfer at least a portion of the absorbed heat to the pipe via the layer of compressible TIM.

### BRIEF DESCRIPTION OF THE DRAWINGS

FIG. 1A illustrates an example vehicle that may be operated in accordance with certain embodiments.

FIG. 1B illustrates a chassis of a vehicle having multiple drive units that may be operated in accordance with certain embodiments.

FIG. 2A is a schematic block diagram of components of a vehicle in accordance with certain embodiments.

FIG. 2B is a schematic block diagram of alternative components of a vehicle in accordance with certain embodiments.

FIG. 3A illustrates a thermal cooling system for a printed circuit board assembly in accordance with certain embodiments.

FIG. 3B illustrates a cross-sectional view of the thermal cooling system of FIG. 3A in accordance with certain embodiments.

FIG. 4A illustrates another thermal cooling system for a printed circuit board assembly in accordance with certain embodiments.

FIG. 4B illustrates a thickness of a compressible thermal interface material (TIM) used to fill a gap between a pipe and heat spreader depicted in FIG. 4A in accordance with certain embodiments.

FIG. 4C illustrates a thickness of a layer of TIM used to fill a gap between the first printed circuit board assembly and heat spreader depicted in FIG. 4A in accordance with certain embodiments.

FIG. 4D illustrates a thickness of a layer of TIM used to fill a gap between the second printed circuit board assembly and heat spreader depicted in FIG. 4A in accordance with certain embodiments.

FIG. 5 illustrates another thermal cooling system for circuit boards of a control system for a vehicle in accordance with certain embodiments.

### DETAILED DESCRIPTION

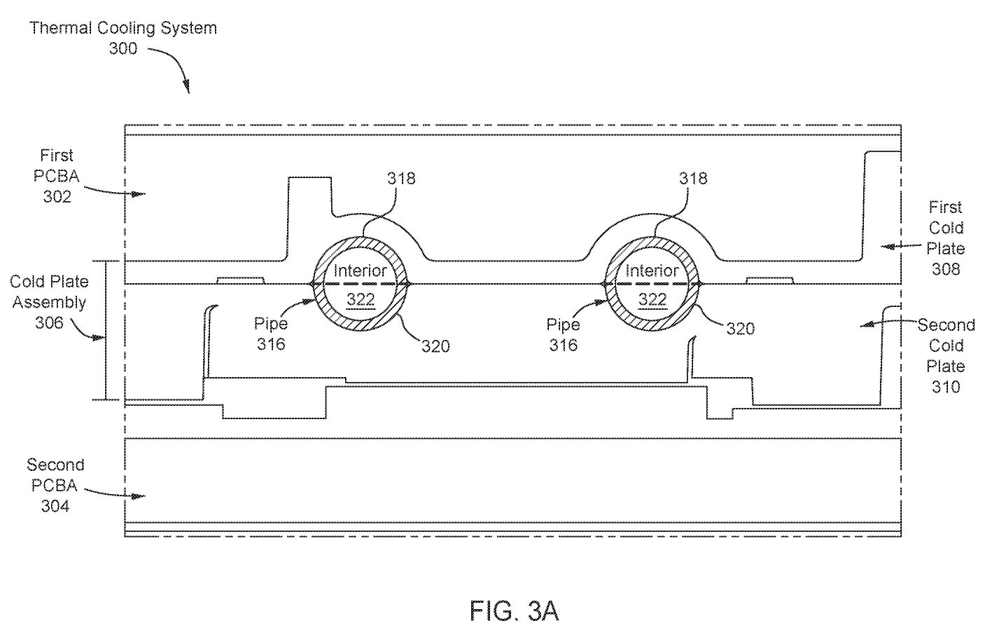

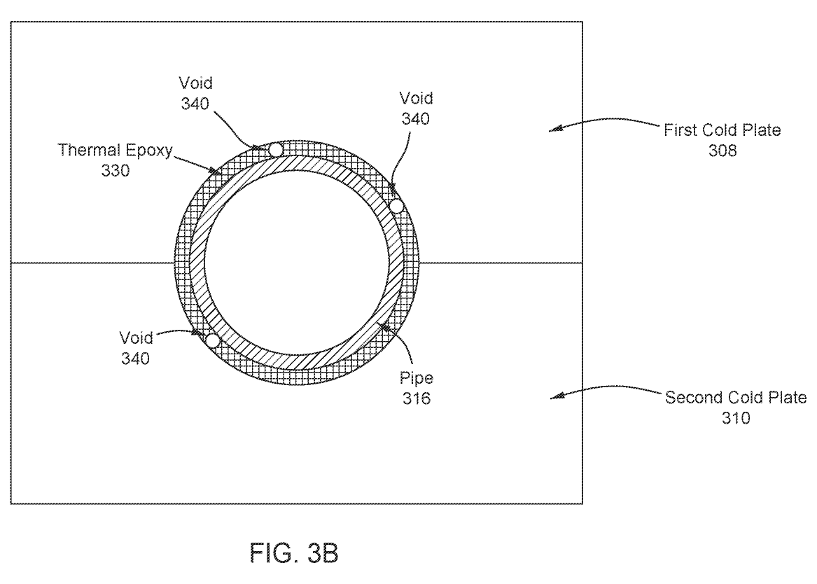

Control systems for vehicles may include multiple printed circuit board assemblies (PCBAs). Each of the PCBAs may include heat-generating components (e.g., central processing unit (CPU), graphics processing unit (GPU), etc.). Thermal cooling systems may be used to dissipate heat generated by the PCBAs. As will be discussed in more detail with reference to FIGS. 3A and 3B, conventional thermal cooling systems include a cold plate assembly that includes a first cold plate thermally coupled to a first printed circuit board assembly (PCBA) and a second cold plate thermally coupled to a second PCBA. In this manner, heat generated by the first PCBA may be transferred to the first cold plate, and heat generated by the second PCBA may be transferred to the second cold plate. The cold plate assembly further includes multiple pipes sandwiched between the first cold plate and the second cold plate and through which a coolant (e.g., ethylene glycol, water, etc.) flows. As the coolant flows through the pipes, heat absorbed by the first cold plate and the second cold plate may be transferred to the coolant and carried away from the cold plates.

Conventional thermal cooling systems use a thermal epoxy to facilitate heat transfer from the cold plates to the pipe. For instance, the thermal epoxy may fill a void (e.g., gap) between the cold plates and each of the respective pipes. However, irregularities on the surfaces of the cold plates and/or the pipe may cause the heat transfer from the cold plates to the pipe via the thermal epoxy to be sub-optimal. Accordingly, improved thermal cooling systems for PCBAs are needed.

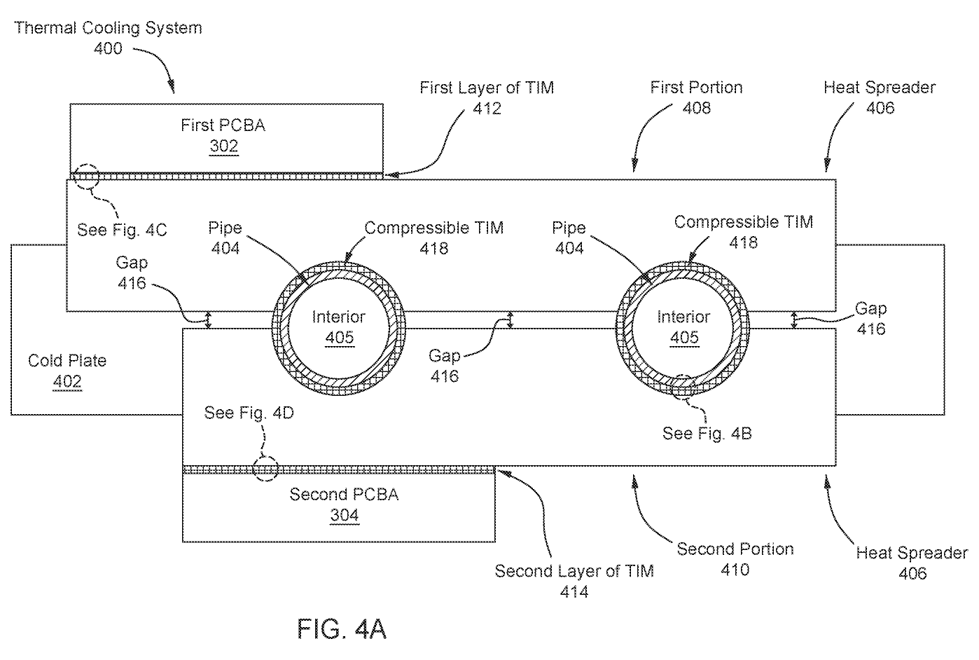

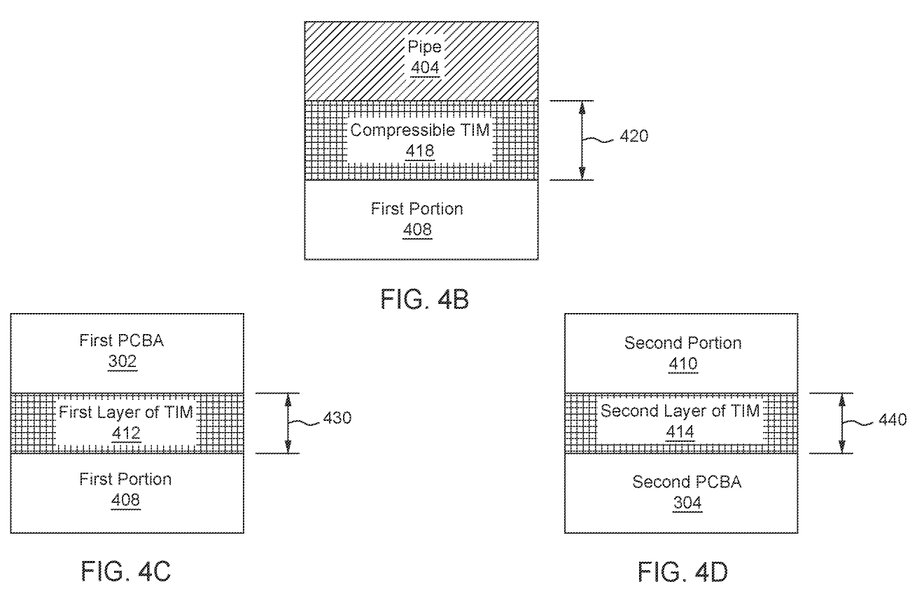

Example aspects of the present disclosure are directed to improved thermal cooling systems for PCBAs. As will be discussed in more detail with reference to FIGS. 4A-4C, thermal cooling systems according to the present disclosure may include a cold plate and a plurality of pipes. Each of the pipes may extend through respective channels defined by the cold plate. Thermal cooling systems according the present disclosure may further include a compressible thermal interface material (TIM) and a heat spreader. The compressible TIM may extend around an outer surface of each of the pipes and the heat spreader may be configured to transfer heat absorbed from one or more heat sources, such as one or more PCBAs, to the pipes via the compressible TIM. Furthermore, the compressible TIM may be compressed between the heat spreader and each respective pipe such that the compressible TIM may conform to the surface of the heat spreader and the surface of each respective pipe. For instance, a force may be applied to the heat spreader to compress the compressible TIM to compensate for irregularities (e.g., air bubbles) in the compressible TIM itself as well as irregularities in the surface of the heat spreader and/or the surface of each respective pipe. In this manner, thermal cooling systems according to the present disclosure may provide improved heat transfer to the pipes (and thus the coolant flowing through the pipes) compared to conventional thermal cooling systems.

In various embodiments, the layer of compressible TIM that extends around the perimeter of each of the pipes may include a layer of TIM that is thicker than bond line TIM that may be used to thermally couple the heat spreader to a heat sources, such as a PCBA. For instance, the layer of compressible TIM may generally be thicker than 0.5 millimeters, whereas the bond line TIM may generally be thinner than 0.1 millimeters. Furthermore, since the layer of compressible TIM is thicker than the bond line TIM, applying a compressive force to the layer of compressible TIM may result in the thickness of the layer of compressible TIM being reduced by a greater percentage relative to the bond line TIM, if each were subjected to the same compressive force. For instance, the layer of compressible TIM may be compressed such that the thickness of the layer of compressible TIM is reduced by about 10 percent to about 70 percent. In this manner, unlike the bond line TIM, the layer of compressible TIM may conform to geometric variations in the surface of a respective pipe and/or the surface of the heat spreader and, as a result, may provide improved heat transfer (e.g., compared to bond line TIM) from the heat spreader to the respective pipe. Also, as an example, the compressible TIM may include a putty (e.g., Laird Tputty 607), whereas the bond line TIM may include a grease (e.g., Tgrease 3000).

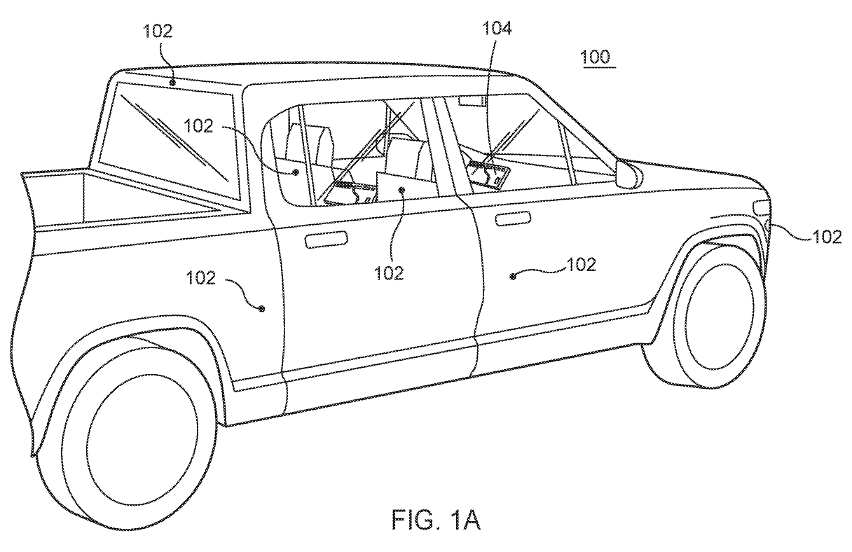

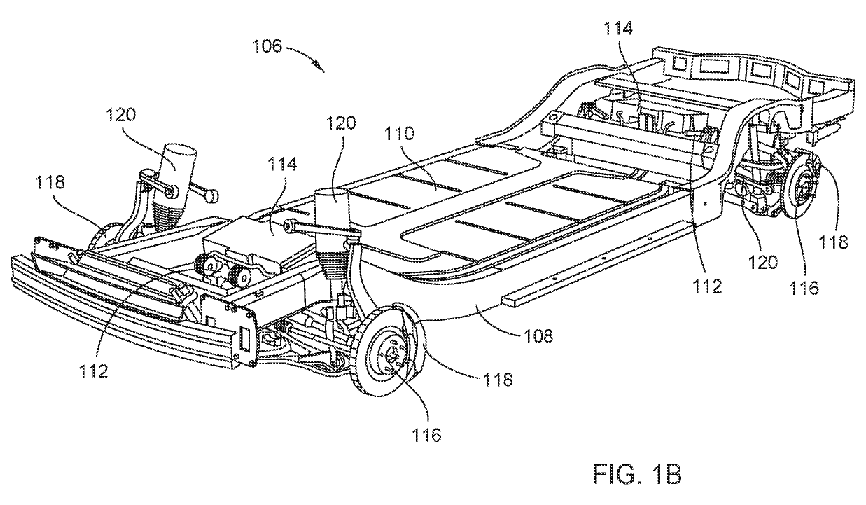

FIG. 1A illustrates an example vehicle 100 in which the approach described herein may be implemented. As seen in FIG. 1A, the vehicle 100 has multiple exterior cameras 102 and one or more front displays 104. Each of these exterior cameras 102 may capture a particular view or perspective on the outside of the vehicle 100. The images or videos captured by the exterior cameras 102 may then be presented on one or more displays in the vehicle 100, such as the one or more front displays 104, for viewing by a driver.

Referring to FIG. 1B, the vehicle 100 may include a chassis 106 including a frame 108 providing a primary structural member of the vehicle 100. The frame 108 may be formed of one or more beams or other structural members or may be integrated with the body of the vehicle (e.g., unibody construction).

In embodiments where the vehicle 100 is a battery electric vehicle (BEV) or possibly a hybrid vehicle, a large battery 110 is mounted to the chassis 106 and may occupy a substantial (e.g., at least 80 percent) of an area within the frame 108. For example, the battery 110 may store from 100 to 200 kilowatt hours (kWh). The battery 110 may be a lithium-ion battery or other type of rechargeable battery. The battery may be substantially planar in shape.

Power from the battery 110 may be supplied to one or more drive units 112. Each drive unit 112 may be formed of an electric motor and possibly a gear train providing a gear reduction. In some embodiments, there is a single drive unit 112 driving either the front wheels or the rear wheels of the vehicle 100. In another embodiment, there are two drive units 112, each driving either the front wheels or the rear wheels of the vehicle 100. In yet another embodiment, there are four drive units 112, each drive unit 112 driving one of four wheels of the vehicle 100. In still other embodiments, there are three drive units 112 with one drive unit 112 driving the front wheels and two drive units 112 driving the rear wheels or two drive units 112 driving the front wheels and one drive unit 112 driving the rear wheels. Additionally, in various embodiments, a single drive unit 112 may include multiple motors. For example, a single drive unit 112 may include two motors, each of which drives a different rear wheel, or each of which drives a different front wheel.

Power from the battery 110 may be supplied to the drive units 112 by one or more sets of power module 114, such as power module for each drive unit 112 or pair of drive units 112. The power module 114 may include inverters configured to convert direct current (DC) from the battery 110 into alternating current (AC) supplied to the motors of the drive units 112. The power module 114 further facilitate operation of the motors of the drive units as generators to provide regenerative braking. The power module 114 further facilitate the transfer of regenerative current to the battery 110.

The drive units 112 are coupled to two or more hubs 116 to which wheels may mount. Each hub 116 includes a corresponding brake 118, such as the illustrated disc brakes. Each hub 116 is further coupled to the frame 108 by a suspension 120. The suspension 120 may include metal or pneumatic springs for absorbing impacts. The suspension 120 may be implemented as a pneumatic or hydraulic suspension capable of adjusting a ride height of the chassis 106 relative to a support surface. The suspension 120 may include a damper with the properties of the damper being either fixed or adjustable electronically.

In the embodiment of FIG. 1B and in the discussion below, the vehicle 100 is a battery electric vehicle. However, a hybrid-electric vehicle may also benefit from the approach described herein. Likewise, non-vehicular applications that use an inverter or other relevant power component may also benefit from the approach described herein.

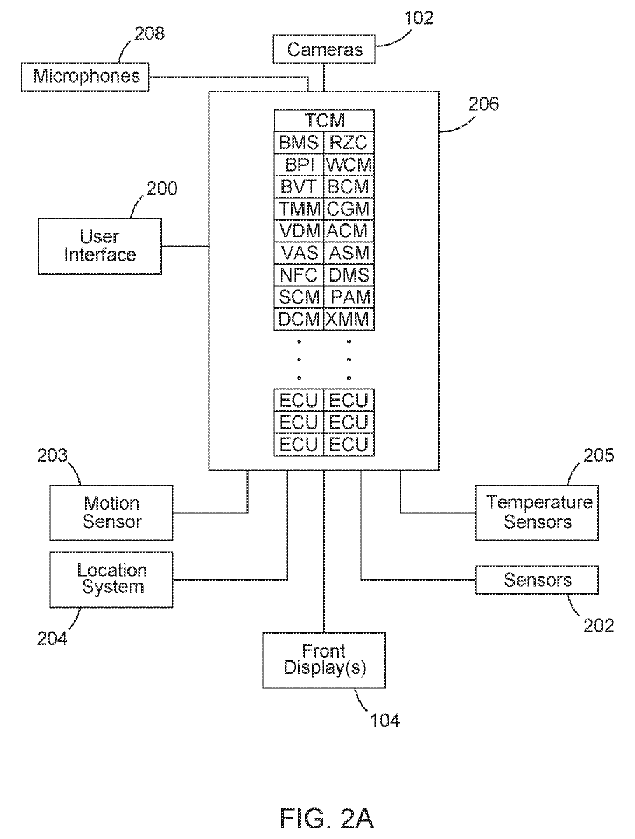

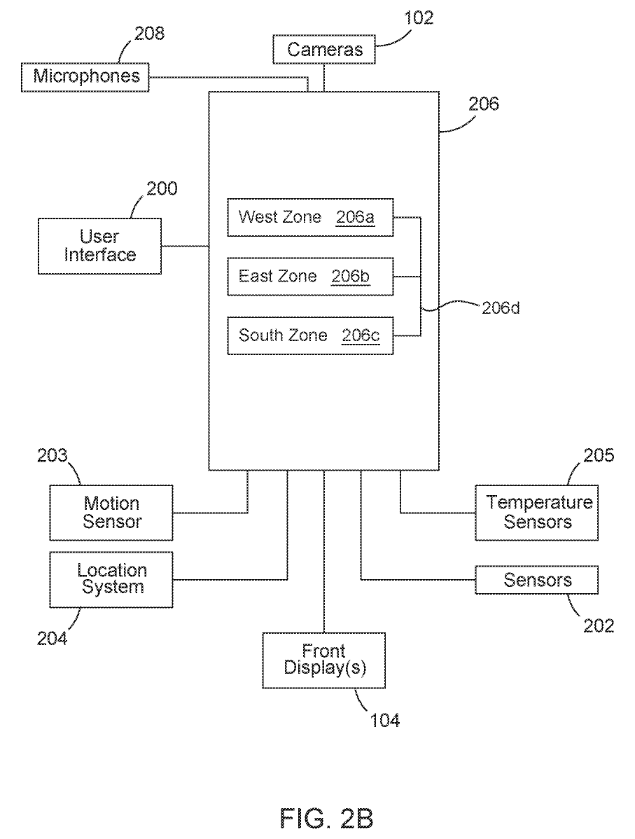

FIG. 2A illustrates example components of the vehicle 100 of FIG. 1A. As shown in FIG. 2A, the vehicle 100 includes the cameras 102, the one or more front displays 104, a user interface 200, one or more sensors 202, a motion sensor 203, and a location system 204. The one or more sensors 202 may include ultrasonic sensors, radio detection and ranging (RADAR) sensors, light detection and ranging (LIDAR) sensors, or other types of sensors. The location system 204 may be implemented as a global positioning system (GPS) receiver. The user interface 200 allows a user, such as a driver or passenger in the vehicle 100, to provide input.

The components of the vehicle 100 may include one or more temperature sensors 205. The temperature sensors 205 may include sensors configured to sense an ambient air temperature, temperature of the battery 110, temperature of power electronics 114, temperature of each drive unit 112 and/or each motor of each drive unit 112, or the temperature of any other component of the vehicle 100.

A control system 206 executes instructions to perform at least some of the actions or functions of the vehicle 100. For example, as shown in FIG. 2A, the control system 206 may include one or more electronic control units (ECUs) configured to perform at least some of the actions or functions of the vehicle 100. In certain embodiments, each of the ECUs is dedicated to a specific set of functions. Each ECU may be a computer system.

Certain features of the embodiments described herein may be controlled by a Telematics Control Module (TCM) ECU. The TCM ECU may provide a wireless vehicle communication gateway to support functionality such as, by way of example and not limitation, over-the-air (OTA) software updates, communication between the vehicle and the internet, communication between the vehicle and a computing device, in-vehicle navigation, vehicle-to-vehicle communication, communication between the vehicle and landscape features (e.g., automated toll road sensors, automated toll gates, power dispensers at charging stations), or automated calling functionality.

Certain features of the embodiments described herein may be controlled by a Central Gateway Module (CGM) ECU. The CGM ECU may serve as the vehicle’s communications hub that connects and transfer data to and from the various ECUs, sensors, cameras, microphones, motors, displays, and other vehicle components. The CGM ECU may include a network switch that provides connectivity through Controller Area Network (CAN) ports, Local Interconnect Network (LIN) ports, and Ethernet ports. The CGM ECU may also serve as the master control over the different vehicle modes (e.g., road driving mode, parked mode, off-roading mode, tow mode, camping mode), and thereby control certain vehicle components related to placing the vehicle in one of the vehicle modes.

In various embodiments, the CGM ECU collects sensor signals from one or more sensors of vehicle 100. For example, the CGM ECU may collect data from cameras 102 and sensors 202. The sensor signals collected by the CGM ECU are then communicated to the appropriate ECUs.

The control system 206 may also include one or more additional ECUs, such as, by way of example and not limitation: a Vehicle Dynamics Module (VDM) ECU, an Experience Management Module (XMM) ECU, a Vehicle Access System (VAS) ECU, a Near-Field Communication (NFC) ECU, a Body Control Module (BCM) ECU, a Seat Control Module (SCM) ECU, a Door Control Module (DCM) ECU, a Rear Zone Control (RZC) ECU, an Autonomy Control Module (ACM) ECU, an Autonomous Safety Module (ASM) ECU, a Driver Monitoring System (DMS) ECU, and/or a Winch Control Module (WCM) ECU. If vehicle 100 is an electric vehicle, one or more ECUs may provide functionality related to the battery pack of the vehicle, such as a Battery Management System (BMS) ECU, a Battery Power Isolation (BPI) ECU, a Balancing Voltage Temperature (BVT) ECU, and/or a thermal Management Module (TMM) ECU. In various embodiments, the XMM ECU transmits data to the TCM ECU (e.g., via Ethernet, etc.). Additionally or alternatively, the XMM ECU may transmit other data (e.g., sound data from microphones 208, etc.) to the TCM ECU.

Referring to FIG. 2B, in some embodiments, the control system 206 may be implemented as a plurality of zonal controllers 206a, 206b, 206c. Each zonal controller 206a, 206b, 206c may control a subset of systems of the vehicle. The subset of systems controlled by each zonal controller 206a, 206b, 206c may be generally assigned based on location within the vehicle 100. For example, a west zonal controller 206a may control systems on a driver side of the vehicle 100, an east zonal controller 206b may control systems on a passenger side of the vehicle 100, and a south zonal controller 206c may control systems in a rear portion of the vehicle. Each zonal controller 206a, 206b, 206c may implement a portion of the functions ascribed to the ECUs of the control system 206 of FIG. 2A. The functions of the ECUs may be distributed among the zonal controller 206a, 206b, 206c such that only one zonal controller 206a, 206b, 206c implements the functions of each ECU. Alternatively, the functions of an ECU may be duplicated across multiple zonal controllers 206a, 206b, 206c, each zonal performing the functions of the ECU for the portion of the vehicle to which that zonal controller 206a, 206b, 206c is assigned.

The zonal controllers 206a, 206b, 206c may be connected to one another by a network 206d, such as an Ethernet network, controller area network (CAN), or other type of network.

FIGS. 3A and 3B depict a thermal cooling system 300 for cooling a first printed circuit board assembly (PCBA) 302 and a second PCBA 304. In some embodiments, the first PCBA 302 and the second PCBA 304 may be part of a control system for a vehicle, such as the control system 206 discussed above with reference to FIG. 2A.

The first PCBA 302 and the second PCBA 304 may each include a system-on-a-chip (SoC) that includes various electronic components. Examples of such electronic components may include, without limitation, central processing units (CPUs), graphics processing units (GPUs), memory, wireless communication modules, and any other suitable type of electronic components.

The thermal cooling system 300 may include a cold plate assembly 306 to provide cooling for heat-generating components (e.g., electronic components) included on the first PCBA 302 and the second PCBA 304. In some embodiments, the cold plate assembly 306 may include a first cold plate 308 that is thermally coupled the first PCBA 302 and a second cold plate 310 that is thermally coupled to the second PCBA 304.

In some embodiments, a thermal interface material (TIM) may be used to thermally couple the first cold plate 308 and the second cold plate 310 to the first PCBA 302 and the second PCBA 304, respectively. For instance, a first layer of TIM may be positioned between the first PCBA 302 and the first cold plate 308 and a second layer of TIM may be positioned between the second PCBA 304 and the second cold plate 310. In this manner, heat generated by the first PCBA 302 may transfer to the first cold plate 308 via the first layer of TIM. Furthermore, heat generated by the second PCBA 304 may transfer to the second cold plate 310 via the second layer of TIM. Examples of the TIM may include a putty (e.g., Laird Tputty 607) or a grease (e.g., Tgrease 3000). It should be appreciated, however, that any suitable type of TIM may be used to thermally couple the first PCBA 302 to the first cold plate 308 and to thermally couple the second PCBA 304 to the second cold plate 310.

The cold plate assembly 306 may include a plurality of pipes 316 positioned (e.g., sandwiched) between the first cold plate 308 and the second cold plate 310. More specifically, the first cold plate 308 may cover an upper portion 318 of each of the pipes 316, and the second cold plate 310 may cover a lower portion 320 of each of the pipes 316. In this manner, the first cold plate 308 and the second cold plate 310 may collectively surround the circumference of each of the pipes 316. As used herein, for each respective pipe of the pipes 316, “upper portion 318” may refer to a portion of a respective pipe that is generally above a center point of the respective pipe and “lower portion 320” may correspond to a portion of the respective pipe that is generally below the center point of the respective pipe.

A coolant source may flow a coolant through the interior 322 of each of the pipes 316. In this manner, heat that is transferred into the cold plates (e.g., first cold plate 308 and second cold plate 310) may be absorbed by the coolant and carried away from the cold plates. In some embodiments, the coolant may be ethylene glycol. It should be appreciated, however, that the scope of the present disclosure is intended to cover any suitable type of coolant that may be used to absorb heat that originates from the PCBAs (e.g., first PCBA 302 and second PCBA 304) and is transferred into the cold plates.

In some embodiments, a thermal epoxy 330 may be used to facilitate heat transfer from the cold plates 308, 310 to each of the pipes 316. For instance, as illustrated in FIG. 3B, the thermal epoxy 330 may be positioned between a surface of the cold plates 308, 310 and an exterior surface of each of the pipes 316. However, one or more voids 340 may be present in the thermal epoxy 330. Such voids may be caused by irregularities in the surface of the first cold plate 308, the surface of the second cold plate 310, and/or the surface of the pipes 316. For example, irregularities in such surfaces may be caused by non-uniform features (e.g., irregular curvature) in such surfaces. Furthermore, in some instances, the one or more voids 340 may be caused by irregularities in the thermal epoxy 330 itself. For instance, examples of voids 340 in the thermal epoxy 330 may include air bubbles that may prevent the thermal epoxy 330 from fully bonding to the surface of the cold plates 308, 310 and/or the pipes 316.

As will be discussed with reference to FIGS. 4A-4D, example aspects of the present disclosure are directed to thermal cooling systems for PCBAs that provide improved heat dissipation compared to conventional thermal cooling systems for PCBAs, such as the thermal cooling system 300 discussed above with reference to FIGS. 3A and 3B. For instance, thermal cooling systems according to the present disclosure may include a heat spreader and compressible TIM that is sandwiched between the heat spreader and each of a plurality of pipes extending through a cold plate and through which coolant flows to remove heat from the pipes. In contrast to the thermal epoxy that is used in conventional thermal cooling systems, the compressible TIM may, when compressed between the heat spreader and each of the pipes, compensate for irregularities in the compressible TIM itself as well as in the surfaces of the heat spreader and/or the pipes. Additionally, the compressible TIM may generally be more thermally conductive compared to the thermal epoxy, such as the thermal epoxy 330 in FIG. 3B, that is used in conventional thermal cooling systems. In this manner, the transfer of heat from the heat spreader to each of the pipes of thermal cooling systems according to the present disclosure may be improved compared to the transfer of heat from the cold plates to the pipes of conventional thermal cooling systems.

FIGS. 4A depicts a thermal cooling system 400 according to certain embodiments of the present disclosure. The thermal cooling system 400 may be used to dissipate heat generated by one or more heat sources. For example, in some embodiments, the one or more heat sources may include one or more PCBAs. It should be appreciated, however, that the scope of the present disclosure does not limit the thermal cooling system 400 to providing cooling for one or more PCBAs. Thus, it should be understood that the thermal cooling system 400 may be used to provide cooling for any heat-generating sources.

The thermal cooling system 400 may include a cold plate 402 and a plurality of pipes 404 that extend through the cold plate 402. For instance, the cold plate 402 may define a plurality of channels (not shown) that extend through the cold plate 402 along a longest axis thereof, and each respective pipe of the plurality of pipes 404 may be extend through a respective channel of the plurality of channels defined by the cold plate 402.

A coolant may flow through the interior 405 of each of the pipes 404. In this manner, heat may be transferred from the pipes 404 to the coolant. In some embodiments, the coolant may be water. In other embodiments, the coolant may be ethylene glycol. In still other embodiments, the coolant may be propylene glycol. It should be understood that these are examples of the coolant that may be used in the thermal cooling system and it should be appreciated that the scope of the present disclosure is not limited to thermal cooling systems using such coolants and therefore may cover thermal cooling systems using any suitable type of coolant to facilitate heat transfer from the pipes 404 to the coolant.

In some embodiments, the thermal cooling system 400 may include a heat spreader 406 configured to absorb heat generated by the first PCBA 302 and heat generated by the second PCBA 304. For instance, the heat spreader 406 may include a first portion 408 and a second portion 410 that is separate from the first portion 408. The first portion 408 of the heat spreader 406 may be thermally coupled to the first PCBA 302 and the second portion 410 of the heat spreader 406 may be thermally coupled to the second PCBA 304.

In some embodiments, the heat spreader 406 may be formed from a metal. For example, in some embodiments, the heat spreader 406 may be formed from aluminum. In other embodiments, the heat spreader 406 may be formed from copper.

In some embodiments, the thermal cooling system 400 may include a first layer 412 of thermal interface material (TIM) that is coupled between the first PCBA 302 and the first portion 408 of the heat spreader 406. For instance, the first layer 412 of TIM may be bonded to a surface of the first PCBA 302 and a surface of the first portion 408 of the heat spreader 406. In this manner, heat generated by the first PCBA 302 may be transferred to the heat spreader 406, specifically the first portion 408 thereof, via the first layer 412 of TIM.

In some embodiments, the thermal cooling system 400 may include a second layer 414 of TIM that is coupled between the second PCBA 304 and the second portion 410 of the heat spreader 406. For instance, the second layer 414 of TIM may be bonded to a surface of the second PCBA 304 and a surface of the second portion 410 of the heat spreader 406. In this manner, heat generated by the second PCBA 304 may be transferred to the heat spreader 406, specifically the second portion 410 thereof, via the second layer of TIM.

As illustrated in FIG. 4A, in some embodiments, the first portion 408 of the heat spreader 406 and the second portion 410 of the heat spreader 406 may be spaced apart from one another such that a gap 416 is defined between the first portion 408 of the heat spreader 406 and the second portion 410 of the heat spreader 406. The gap 416 may extend along the length of the heat spreader 406 such that the first portion 408 of the heat spreader 406 and the second portion 410 of the heat spreader 406 do not contact (e.g., touch) one another. In some embodiments, a width of the gap 416 may range from about 0.25 millimeters to about 1.25 millimeters.

The thermal cooling system 400 may include a compressible TIM 418 that extends around a perimeter of each of the pipes 404. For instance, the compressible TIM 418 may be coupled to an outer surface of each of the pipes 404 and may extend (e.g, wrap) around the entire perimeter (e.g., circumference) of each of the pipes 404. The compressible TIM 418 may be compressed between the heat spreader 406 and each of the pipes 404. Compression of the compressible TIM 418 may allow the compressible TIM 418 to compensate for irregularities (e.g., air bubbles) in itself as well as irregularities in the surfaces of the heat spreader 406 and/or the respective pipes 404. For instance, air bubbles that may be present in the compressible TIM 418 may be removed (e.g., burst) when a force is applied to the heat spreader 406 to compress the compressible TIM 418. Furthermore, compression of the compressible TIM 418 may allow the compressible TIM to fill voids (e.g., air gaps) between the compressible TIM 418 and the heat spreader 406 and/or the pipes 404 that are caused by irregularities (e.g, corners, non-uniform curvature) in the surface of the heat spreader 406 and/or the pipes 404. In this manner, heat transfer from the heat spreader 406 to each of the pipes 404 via the compressible TIM 418 may be improved compared to heat transfer from the cold plates 308, 310 to the pipes 316 in conventional thermal cooling systems, such as the thermal cooling system 300 discussed above with reference to FIG. 3A. For instance, in some embodiments, the compressible TIM 418 may improve heat transfer from the heat spreader 406 to each of the pipes 404 by greater than 10 degrees Celsius.

In some embodiments, compression of the compressible TIM 418 may cause a portion (e.g., excess) of the compressible TIM 418 to flow into the gap 416 defined between the first portion 408 of the heat spreader 406 and the second portion 410 of the heat spreader 406. For instance, the portion of the compressible TIM 418 may be configured to flow into the gap 416 when a compressive force is applied to the first portion 408 of the heat spreader 406 or the second portion 410 of the heat spreader 406. In this manner, the gap 416 may serve as a channel into which excess of the compressible TIM 418 may flow as the compressible TIM 418 is compressed between the heat spreader 406 and each of the pipes 404. Furthermore, in some embodiments, the gap 416 may be filled with the compressible TIM 418. For instance, the gap 416 may be completely filled with the compressible TIM 418 such that the portions 408, 410 of the heat spreader 406 are thermally coupled to one another via the compressible TIM 418 filling the gap 416.

Referring now to FIGS. 4B, 4C, and 4D, the thicknesses of the compressible TIM 418, the first layer 412 of TIM, and the second layer 414 of TIM are illustrated. As illustrated, the compressible TIM 418 may generally be thicker than the first layer 412 of TIM and the second layer 414 of TIM. For instance, in some embodiments, a thickness 420 of the compressible TIM 418 may range from about 0.2 millimeters to about 2 millimeters. Furthermore, a thickness 430 of the first layer 412 of TIM and a thickness 440 of the second layer 414 of TIM may generally range from about 0.05 millimeters to about 0.15 millimeters.

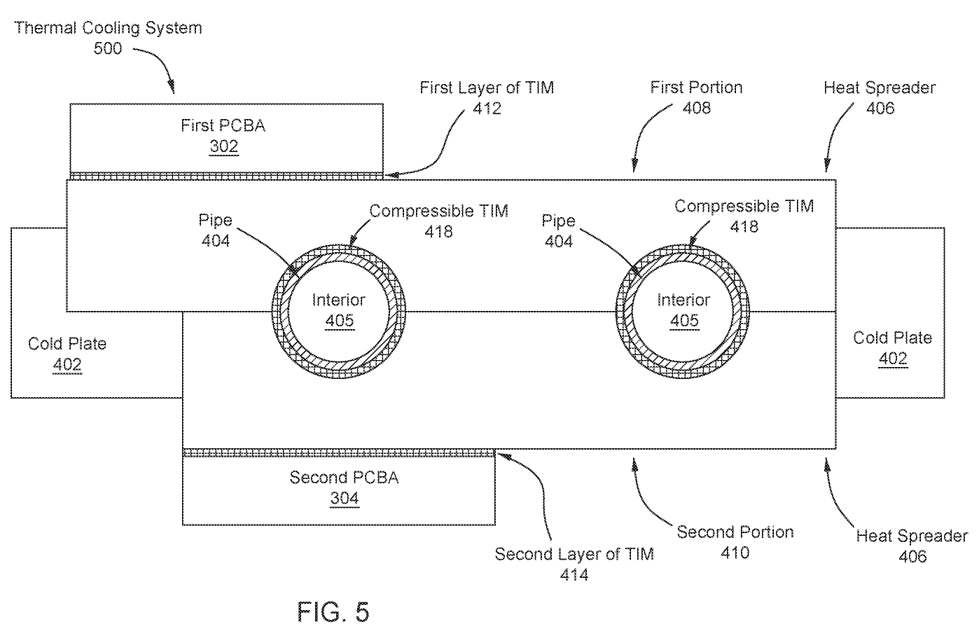

FIG. 5 depicts another embodiment of a thermal cooling system 500 in accordance with certain embodiments of the present disclosure. The thermal cooling system 500 of FIG. 5 may be configured substantially the same as the thermal cooling system 400 discussed above with reference to FIG. 4A. However, in contrast to the thermal cooling system 400 of FIG. 4A, the heat spreader 406 of the thermal cooling system 500 of FIG. 5 may not include the gap 416 defined between the first portion 408 and the second portion 410 thereof. Instead, the first portion 408 of the heat spreader 406 and the second portion 410 of the heat spreader 406 may contact one another such that a surface of the of the first portion 408 of the heat spreader 406 contacts (e.g., touches) a surface of the second portion 410 of the heat spreader 406 along the length of the heat spreader 406. In this manner, by having the first portion 408 and the second portion 410 contact one another such that there is no gap (e.g., gap 416), heat transfer between the first portion 408 and the second portion 410 of the heat spreader 406 illustrated in FIG. 5 may be improved compared to heat transfer between the first portion 408 and the second portion 410 of the heat spreader 406 illustrated in FIG. 4A.

The descriptions of the various embodiments of the present disclosure have been presented for purposes of illustration. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure may exceed the specific described embodiments. Instead, any combination of the features and elements, whether related to different embodiments, is contemplated to implement and practice contemplated embodiments. Furthermore, although embodiments disclosed herein may achieve advantages over other possible solutions or over the prior art, the embodiments may achieve some advantages or no particular advantage. Thus, the aspects, features, embodiments and advantages discussed herein are merely illustrative.

While the foregoing is directed to embodiments of the present disclosure, other and further embodiments may be devised without departing from the basic scope thereof, and the scope thereof is determined by the claims that follow.

What is claimed is:

1. A thermal cooling system, comprising:
a cold plate defining a channel;
a pipe extending through the channel;
a layer of compressible thermal interface material (TIM) extending around a perimeter of the pipe; and
a heat spreader configured to absorb heat generated by one or more heat sources, the heat spreader further configured to transfer at least a portion of the absorbed heat to the pipe via the layer of compressible TIM.

2. The thermal cooling system of claim 1, wherein the heat spreader comprises:
a first portion that is thermally coupled to a first printed circuit board assembly (PCBA); and
a second portion that is thermally coupled to a second PCBA, the second portion being in contact with the first portion.

3. The thermal cooling system of claim 1, wherein the heat spreader comprises:
a first portion that is thermally coupled to a first PCBA; and
a second portion that is thermally coupled to a second PCBA, the second portion positioned relative to the first portion such that a gap is defined between the first portion and the second portion.

4. The thermal cooling system of claim 3, wherein a portion of the layer of compressible TIM is configured to flow into the gap when a force is applied to the first portion of the heat spreader or the second portion of the heat spreader.

5. The thermal cooling system of claim 3, wherein a width of the gap is about 0.25 millimeters to about 1.25 millimeters.

6. The thermal cooling system of claim 1, wherein the heat spreader is thermally coupled to the one or more heat sources via one or more layers of TIM.

7. The thermal cooling system of claim 6, wherein the layer of compressible TIM extending around the perimeter of the pipe is thicker than each of the one or more layers of TIM.

8. The thermal cooling system of claim 7, wherein a thickness of the layer of compressible TIM is about 0.2 millimeters to about 2 millimeters.

9. The thermal cooling system of claim 1, wherein the heat spreader comprises a metal.

10. The thermal cooling system of claim 9, wherein the metal comprises aluminum or copper.

11. A thermal cooling system for printed circuit board assemblies, comprising:
a cold plate defining a channel;
a pipe extending through the channel;
a layer of compressible thermal interface material (TIM) extending around a perimeter of the pipe; and
a heat spreader configured to absorb heat generated by one or more printed circuit board assemblies (PCBAs), the heat spreader further configured to transfer at least a portion of the absorbed heat to the pipe via the layer of compressible TIM.

12. The thermal cooling system of claim 11, wherein the heat spreader comprises:
a first portion that is thermally coupled to a first printed circuit board assembly (PCBA); and
a second portion thermally coupled to a second PCBA, the second portion being in contact with the first portion.

13. The thermal cooling system of claim 11, wherein the heat spreader comprises:
a first portion that is thermally coupled to a first printed circuit board assembly (PCBA); and
a second portion that is thermally coupled to a second PCBA, the second portion positioned relative to the first portion such that a gap is defined between the first portion and the second portion.

14. The thermal cooling system of claim 13, wherein a portion of the layer of compressible TIM is configured to flow into the gap when a force is applied to the first portion of the heat spreader or the second portion of the heat spreader.

15. The thermal cooling system of claim 13, wherein a width of the gap is about 0.25 millimeters to about 1.25 millimeters.

16. The thermal cooling system of claim 11, wherein the heat spreader is thermally coupled to the one or more printed circuit board assemblies via one or more layers of TIM.

17. The thermal cooling system of claim 16, wherein the layer of compressible TIM extending around the perimeter of the pipe is thicker than the one or more layers of TIM.

18. The thermal cooling system of claim 17, wherein a thickness of the layer of compressible TIM is about 0.2 millimeters to about 2 millimeters.

19. The thermal cooling system of claim 11, wherein the heat spreader comprises a metal.

20. The thermal cooling system of claim 19, wherein the metal comprises aluminum or copper.
